(19) United States
(12) Patent Application Publication
(10) Pub. No.: US 2007/0257366 A1
(43) Pub. Date: Nov. 8, 2007

(54) Barrier layer for semiconductor interconnect structure

(75) Inventors: Yu-Sheng Wang, Tainan City (TW); Jung-Chih Tsao, Taipei City (TW); Kei-Wei Chen, Taipei (TW); Shih-Chieh Chang, Tainan (TW); Ying-Lang Wang, Tai-Chung County (TW)

Correspondence Address: SLATER & MATSIL, L.L.P., 17950 PRESTON ROAD, SUITE 1000, DALLAS, TX, 75252, US

(73) Assignee: Taiwan Semiconductor Manufacturing Company, Ltd.

(21) Appl. No.: 11/416,945

(22) Filed: May 3, 2006

(51) Int. Cl. H01L 21/4763

(52) U.S. Cl. 257/751; 438/627

(57) ABSTRACT

A method for producing a semiconductor-device having an electrical interconnect. The method produces having an improved barrier layer between the interconnect conductor and the dielectric material in which the interconnect recess is formed. A dielectric layer is formed on top of a wafer substrate having at least one contact region. An interconnect for servicing the contact region is fabricated by forming an interconnect recess and then depositing a primary barrier layer of tantalum nitride and subjecting it to a re-sputtering operation. A film layer of tantalum is then deposited and re-sputtered. Following this operation, a seed layer is formed, and then a conductor is used to fill the interconnect recess. Planerizing the surface of the wafer so that further fabrication may be performed may complete the process.

### TECHNICAL FIELD

The present invention relates generally to the fabrication of semiconductor devices, and more particularly to a method for fabricating an improved barrier layer structure for a semiconductor-device electrical interconnect that yields improved resistivity characteristics and provides better control in the fabrication process.

### BACKGROUND

The myriad small electronic devices in use today, including computers, cellular telephones, and portable game-station, have been made possible in large part by the development of semiconductor electronics technology. Semiconductors are materials that conduct electricity only under certain conditions, which often include the presence of a small electrical charge in the form of an applied voltage. This property enables the manufacture of solid-state switches—those that have no moving parts. Unlike former technology that relied on electromechanical switches and wires, integrated circuits made of semi-conducting materials have no moving parts, take up far less space, and can operate on much less power—all desirable features for components used in modern electronic devices.

Because of their small size, semiconductor devices require a specialized fabrication process. A series of steps is used to simultaneously form a large number of components on a single work piece. The specific steps involved in fabricating a particular combination of these tiny semiconductor devices may vary, but similar general steps are employed. A material such as silicon is produced for use as a base, or substrate material. This material is then cut into an appropriate shape, typically a thin slice called a wafer. The pure silicon is then selectively treated with one or more materials called dopants, such as ionized boron or phosphorus. The introduction of these impurities begins the process of creating the desired semiconductive properties. Various structures are then formed at or near a surface of the wafer in a series of steps. These structures will eventually make up the transistors, capacitors, and other electrical components of the particular semiconductor device.

These surface structures may be formed for example by etching, whereby the surface is exposed to an appropriate etching agent. Or, more typically, the surface is selectively etched using a process known as photolithography. In photolithography, a material called photoresist, or simply resist, is deposited and spread evenly over the wafer surface. The resist is then selectively treated with a light source directed though a patterned mask so that some portions of the resist are exposed to the light energy and others are not. The exposed portions of the photoresist are either strengthened or weakened, depending on the type of resist material used, so that the weaker portions can be washed away using a solvent that will not otherwise affect the wafer or any structures already formed on it. The resist that remains, however, will prevent the etching of the wafer surface in the still-covered areas when the etching agent is used in subsequent steps. When the desired wafer etching has been accomplished, the remaining photoresist is removed using an appropriate solvent. Etching is only one method of removing material, however, and other methods including mechanical scrubbing are also used.

Materials are added to the wafer during the fabrication process as well. Metals, other conductors, and insulators are added to the wafer surface using any of a variety of deposition methods, for example chemical vapor deposition (CVD) or sputtering. Additional ion implantation may also be performed. By selectively adding and removing these various materials, layer after layer of electrical devices can be formed on the wafer surface (or on top of previously formed structures).

A single wafer is typically used for the fabrication of a number of dice, or portions of the wafer that will eventually be used separately. Typically, all of the dice on a single wafer are formed identically, but this is not necessarily the case. After the fabrication is complete (and often at various intermediate steps as well), the wafer is inspected so that defective regions can be marked for discard or repair. The dice are eventually separated and those passing inspection are packaged, that is encapsulated in a hard plastic material and provided with external leads connected to various internal locations. The encapsulated die that has been provided with a number of leads is often referred to as a chip.

There are many types of electrical devices that can be fabricated using methods like those described above, and a single chip contains thousands, or even millions of such devices, arranged to form functioning circuits. At times it is necessary to connect one circuit or device with another one that is not immediately adjacent to it. An interconnect may be used for this purpose. A typical interconnect structure is shown in FIGS. 1A and 1B. FIG. 1A is a cross-sectional side view of semiconductor device 100. FIG. 1B is a cross-sectional side view of semiconductor device 100, rotated 90° from the view of FIG. 1A. Semiconductor device 100, formed on substrate 101, includes a first electrical circuit and a second electrical circuit, the two of which need to be connected for the device to operate. The specific function of these circuits is not relevant here, and for convenience they will be referred to as first active area 105 and second active area 110. These active areas are formed on substrate 101 in a first layer 102. Note that as used herein, the term “semiconductor device” may refer to a complete device that will function as a unit, but more frequently it will simply refer to a component or collection of components that will make up but a small portion of such a unit.

An elongated conductor 115 formed in trench 116 is used to electrically connect first active area 105 and second active area 110. Elongated conductor 115 is located in interconnect layer 103, and is constructed of a conducting material such as aluminum or copper. To make sure the elongated conductor 115 does not contact any other portions of the semiconductor device (unless it is intended to do so), a dielectric material 120 surrounds it, locally filling in much of the remainder of layer 103. (Although not shown in FIGS. 1A and 1B, an insulating layer or additional interconnect structures, or both, are likely to be disposed in an additional layer above layer 103.) To establish an electrical connection with the appropriate active areas, vias are formed, extending downward from trench 116, and also filled with the conductive material of elongated conductor 115. As illustrated in FIGS. 1A and 1B, via 117 extends to contact active area 105 and via 118 extends to contact active area 110.

The interconnect of FIGS. 1A and 1B is adequate for use in many semiconductor applications. As the drive continues to design chips containing a greater number of electrical devices in smaller and smaller packages, however, problems associated with heat dissipation, stress migration, and mechanical strength, among other factors, become more pronounced. Improvement in design to deal with these problems is constantly demanded. The present invention provides just such an improvement.

### SUMMARY OF THE INVENTION

These and other problems are generally solved or circumvented, and technical advantages are generally achieved, by preferred embodiments of the present invention such as those described herein. In accordance with a preferred embodiment of the present invention, a method for fabricating a semiconductor device includes the steps of providing a substrate such as a silicon wafer. The substrate includes a contact region to which an electrical contact is to be made, and a dielectric layer is deposited over the substrate and the contact region. An interconnect recess is then formed in the dielectric material, preferably by forming a trench region and a number of via regions either simultaneously or in sequence. A primary film layer is then deposited over the dielectric material and a re-sputtering operation is performed. The primary film layer is preferably in the range of approximately 50 Å to 150 Å thick, with an optimum thickness of approximately 135 Å. A secondary film layer is then deposited over the primary film layer and a re-sputtering operation is performed. The secondary film layer, in one embodiment, has a minimum thickness of approximately 50 Å. Ideally, the re-sputtering of the secondary film layer results in a grain density of approximately 3.5 per 100 nm or less. A seed layer is then formed on the secondary film layer, followed by deposition of the main conductor material. The excess conducting material may then be removed to planerize the wafer surface, for example by chemical mechanical polishing (CMP).

In a particularly preferred embodiment, the primarily-formed film layer is a tantalum nitride (TaN) material and the secondarily formed layer is a tantalum (Ta) material. In this embodiment, argon plasma is in a saturate environment is used for the re-sputtering operations. Copper is a preferred conductor for both the seed layer and the main conductor portions. In an alternate embodiment, the re-sputtering operation is performed only after the secondary film layer has been formed.

Another preferred embodiment of the present invention is an interconnect for electrically coupling one contact region formed on a semiconductor wafer with another contact region, the interconnect structure formed in a dielectric layer deposited over the substrate containing a contact region, which my be the wafer base substrate or a higher layer of a semiconductor device being fabricated. In a recess formed in the dielectric layer, a barrier layer is formed by deposition of a TaN film layer followed by a Ta layer, the barrier layer being then subjected to a re-sputtering operation. In another embodiment, re-sputtering, preferably with an argon plasma, is performed after the formation of each of the separate film layers of the barrier layer. In either case, the remaining portion of the interconnect recess is filled with a conductive material, preferably copper.

An advantage of a preferred embodiment of the present invention is the formation of a relatively impervious barrier layer that helps prevent intrusion of the conductor material into the dielectric layer material, while at the same time lowering ht resistivity characteristics of the interconnect structure.

As more complete appreciation of the present invention and the scope thereof can be obtained from the accompanying drawings that are briefly summarized below, the following detailed description of the presently-preferred embodiments of the present invention, and the appended claims.

### BRIEF DESCRIPTION OF THE DRAWINGS

For a more complete understanding of the present invention, and the advantages thereof, reference is now made to the following descriptions taken in conjunction with the accompanying drawing, in which:

FIG. 1A is a cross-sectional side view of a typical semiconductor device of the prior art. FIG. 1B is a cross-sectional side view of this semiconductor device, rotated 90° from the view of FIG. 1A.

FIG. 2 is a flow diagram illustrating a basic method for fabricating a semiconductor device including an interconnect structure, in which an embodiment of the present invention may be advantageously employed.

FIG. 3 is a cross sectional elevation view illustrating a portion of an exemplary semiconductor device fabricated according to the process of FIG. 2.

FIG. 4 is a cross sectional elevation view illustrating a semiconductor device structure according to an embodiment of the present invention.

FIG. 5 is a flow diagram illustrating a method for fabricating a semiconductor device including an interconnect structure according to an embodiment of the present invention.

FIGS. 6A though 6J are cross-sectional elevation views illustrating a semiconductor device at selected stages of fabrication according to an embodiment of the present invention.

### DETAILED DESCRIPTION OF ILLUSTRATIVE EMBODIMENTS

Presently preferred embodiments of the present invention and their implementation are discussed in detail below. It should be appreciated, however, that the present invention provides many applicable inventive concepts that can be embodied in a wide variety of specific contexts. The specific embodiments discussed are merely illustrative of specific ways to make use of the invention, and do not limit the scope of the invention.

The present invention will be described with respect to preferred embodiments in a specific context, namely a semiconductor device including an electrical interconnect for serving as a connection between two or more contact regions on a semiconductor substrate, or on another layer, and a method of forming such an interconnect. The described structure features a dual-damascene trench-and-via structure filled primarily with a copper conductor formed over a barrier layer of tantalum and tantalum nitride. The invention may also be applied, however, to other, similar semiconductor structures and make use of other materials as well.

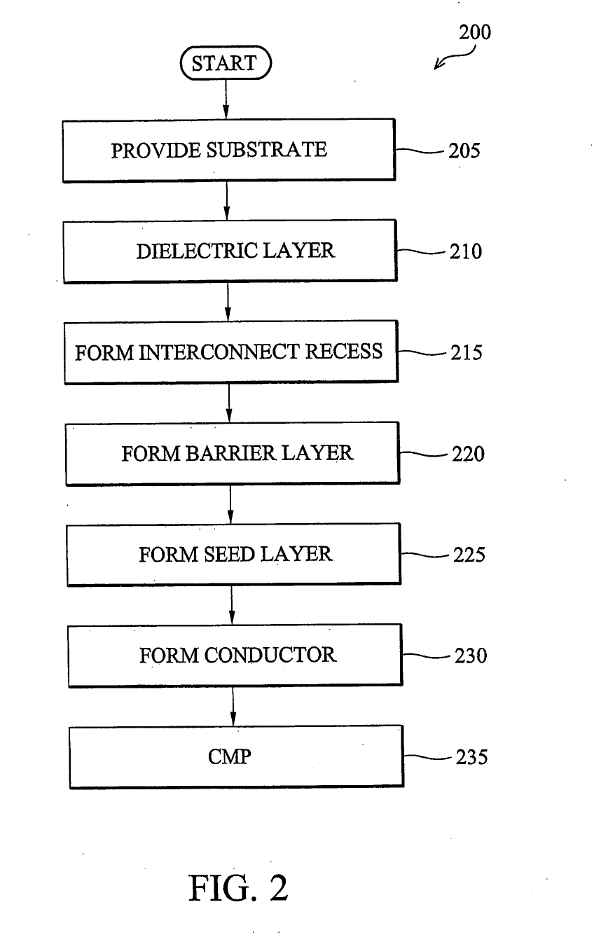

Referring now to FIG. 2, there is illustrated a basic method 200 for interconnect fabrication to which the present invention may be advantageously applied. At START it is presumed that the semiconductor fabrication equipment and the materials needed for fabrication are present and available. This being the case, the process begins with provision of a wafer substrate (step 205). The substrate is formed, for example, of silicon, and generally includes a number of doped regions to provide selected portions of the substrate with desirable electricity-conducting characteristics. A variety of methods are used to form various electrical devices for building functional circuits.

The wafer substrate will typically include a number of active areas. An active area is a functional circuit, or a similar feature, and is often the location to which an external (to the circuit) electrical connection is desired. An interconnect may be used for this purpose. An interconnect may be used to connect a number of different types of active areas, structures, or other locations on the wafer. For convenience, the area that an interconnect is to serve will be referred to herein simply as a ‘contact region’ because the type of area served is not material to the present intention unless specifically recited as such. Similarly, the interconnect may not be present in a layer immediately above the base substrate of the semiconductor wafer but in a higher layer instead. For this reason, the term substrate will sometimes herein be used to refer to whatever wafer level includes the contact region to be served by the interconnect (or similar device) in accordance with the present invention.

The basic method 200 continues with the deposit of an insulating dielectric layer (step 210) of, for example, silicon dioxide. As should be apparent, this layer isolates the functioning circuit devices from those that will be formed above it. At this point it is noted that, while the orientation of the wafer may vary during fabrication, for convenience herein the basic wafer substrate will be described as on the ‘bottom’, with successive layers of various materials placed upon it. A layer or structure that is ‘over’ or ‘above’ another simply means that it is further towards the top of the wafer, that is, the outer surface (at a give time) being used to form the various semiconductor components. ‘Above’ or ‘below’ does not necessarily, however, imply that the layers in question are adjacent to each other unless such a relationship is explicitly stated or apparent from the context. Referring to the process of FIG. 2, for example, the dielectric layer is deposited or otherwise formed directly onto the existing substrate (and upon any structures that have already been formed on or in the substrate).

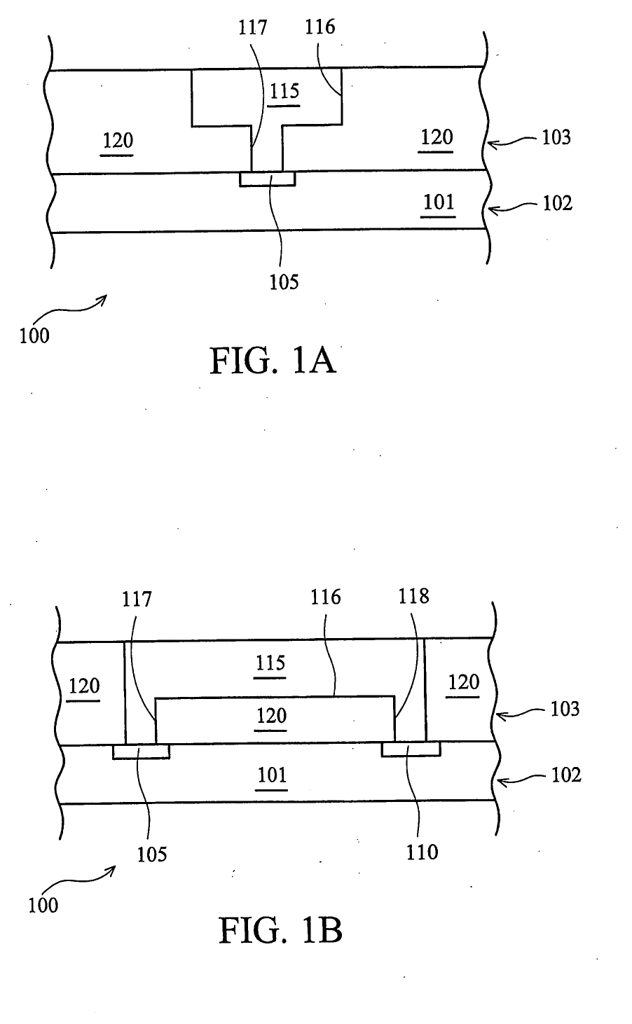

Some portions of the layer underlying the dielectric insulating layer, which at this point is the base substrate, require electrical connections to other areas. These connections may, of course, be established before the insulating dielectric layer is deposited. The dual-damascene method described above, however, is currently and widely used for forming the necessary electrical connections. This type of connection is created after the dielectric layer has been formed, beginning with first forming an interconnect recess (step 215). The interconnect recess typically has a trench portion and one or more via portions (see, for example, FIGS. 1A and 1B). The vias will normally be the positioned adjacent the contact region being served, providing the connection between the contact region and the main conductor disposed in the trench. The trench may be formed at the same time or in the same process step as one or more of the vias, or these portions may be formed at different stages. In the latter case, either the trench portion or the via portions of the interconnect may be formed first.

The interconnect recess, however created, will eventually be filled primarily with a conductive material such as copper. First, however, it is advisable to form a thin barrier layer (step 220) to prevent the conductor material from penetrating the dielectric-layer material at the borders of the recess. Suitable barrier layer materials include silicon nitride and tantalum, although other materials may be used as well. After the barrier layer has been formed, a seed layer is deposited (step 225). The seed layer is formed of a conductive material, which may or may not be the same material as that used for the conductor. The purpose of the seed layer is to serve as a conductor for the electroplating bias voltage that may be used to form the main portion of the conductor. While neither the barrier layer nor the seed layer is required for the interconnect to function, they have been found to be of significant advantage and their use in such devices has become common.

Once the seed layer has been deposited in step 225, the main conductor is then formed (step 230), for example, by electrochemical plating (ECP). In general, this material (and copper is often preferred) will serve as an electrical connection between the two or more contact regions served by the interconnect. The process of depositing the copper conductor frequently involves depositing enough material to fill the interconnect recess (and most likely, many such recesses) completely, resulting in an excess amount of material covering the top surface of the wafer. Some process such as chemical mechanical polishing (CMP) (step 235), may then remove the excess, leaving only the material actually occupying the recess or recesses. The next step in the wafer fabrication may then take place, which will frequently include covering the completed interconnect with an insulative material (step not shown).

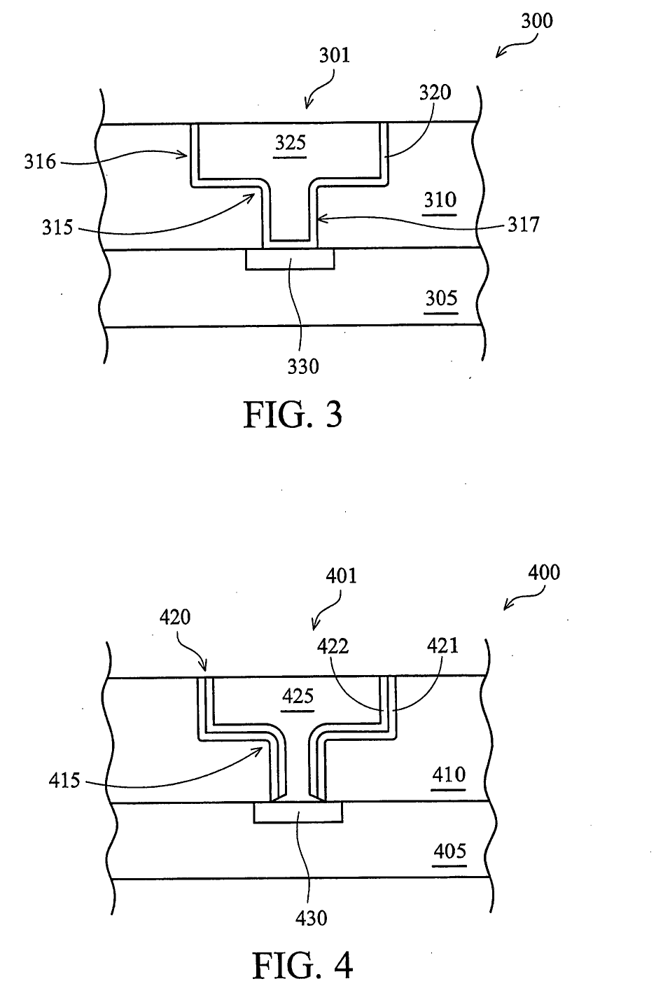

FIG. 3 is a cross sectional elevation view illustrating a portion of an exemplary semiconductor device 300 fabricated according to the basic process 200 of FIG. 2. Semiconductor device 300 includes interconnect structure 301, which in turn includes a trench-and-via type interconnect recess 315 that has been formed in a layer of dielectric material 310 after its deposition on substrate 305. Copper conductive material 325 has been used to fill the interconnect recess 315, and in both the trench portion 316 and in the via portion 317, it is separated from the dielectric material 310 by a barrier layer 320, which was deposited in advance of the conductive material. Note that copper conductive material 325 is configured to be electrically coupled with active area 330 of substrate 305, and also that any excess copper conductive material has already been removed so that the top of the copper conductive material 325 is in a substantially common plane with the top of the surrounding dielectric material 310. The use of barrier layer 320 also helps to avoid the presence of any conductive material outside of the interconnect recess 315, for example by intrusion into the dielectric material 310, where it might contribute to the leakage of electrical current.

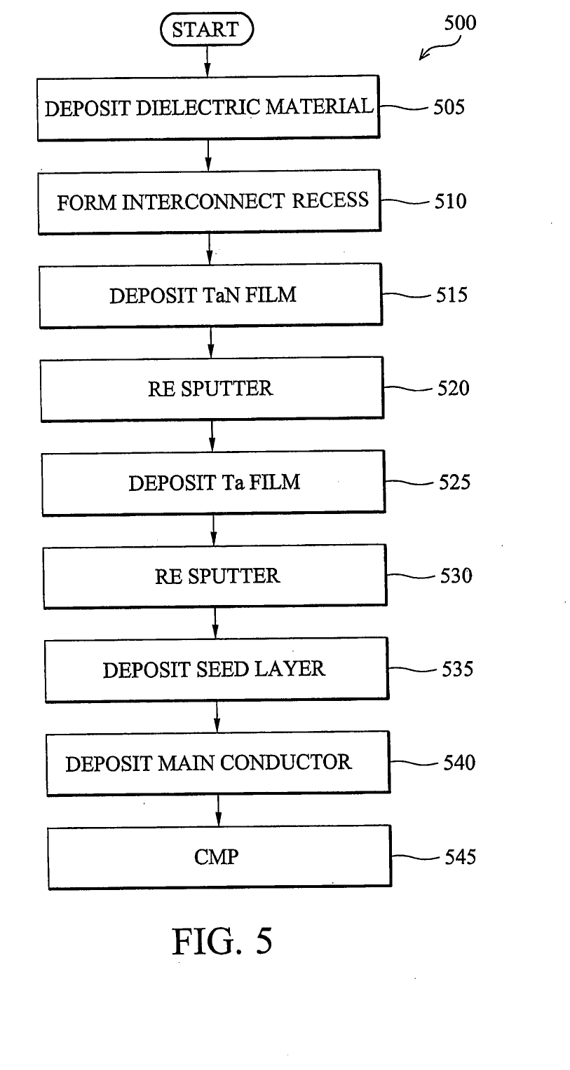

While this basic structure may be expected to provide the known advantages of dual-damascene interconnects, it may also be deficient in a number of ways. Notably, a barrier layer with high resistivity may adversely affect the resistance value of the interconnect itself. A more advantageously-designed and fabricated barrier layer may result in lower barrier resistivity and better performance of the interconnects or similar structures formed in a semiconductor device. FIG. 4 illustrates such as design, in accord with the present invention, and FIG. 5 describes a process by which this device may be fabricated.

FIG. 4 is a cross sectional elevation view illustrating a semiconductor structure 400 according to an embodiment of the present invention. Semiconductor device 400 includes an interconnect structure 401. Interconnect structure 401 includes a conductor 425 preferably of copper, which is formed in an interconnect recess 415. The interconnect structure is itself formed, preferably using a dual-damascene-type process, in a layer of dielectric material 410 that has previously been deposited on substrate 405. Copper conductor 425 couples the active area 430 of substrate 405 with other active areas or components (not shown) of the semiconductor wafer. In a preferred embodiment, to top surface of the copper conductor 425 has been planarized, for example by CMP, so as to be substantially co-planer with the top surface of the dielectric material 410 in which the interconnect structure 401 has been fabricated. Note that the use of copper for the interconnect conductor is preferred but exemplary; other suitable materials may be used as well in accordance with other embodiments.

In the embodiment of FIG. 4, the copper conductor 425 of interconnect structure 401 is separated from the dielectric material 410 by a barrier 420. In accordance with this embodiment of the present invention, the barrier 420 includes a primarily-formed layer 421 secondarily-formed layer 422. As used in this context, the terms ‘primarily-formed’ and ‘secondarily-formed’ herein refer to the sequence in which these two layers were separately formed. In a preferred embodiment, the primarily-formed layer 421 is formed of tantalum nitride (TaN) that has been deposited and re-sputtered, as further described below, and the secondarily-formed layer 422 is formed of tantalum (Ta) using a similar process. During fabrication, a copper seed layer was deposited directly onto the secondarily-formed layer 422, but in the illustration of FIG. 4 it is not visible as separate from copper conductor 425. A process for fabricating the interconnect structure 401 of FIG. 4 will now be described.

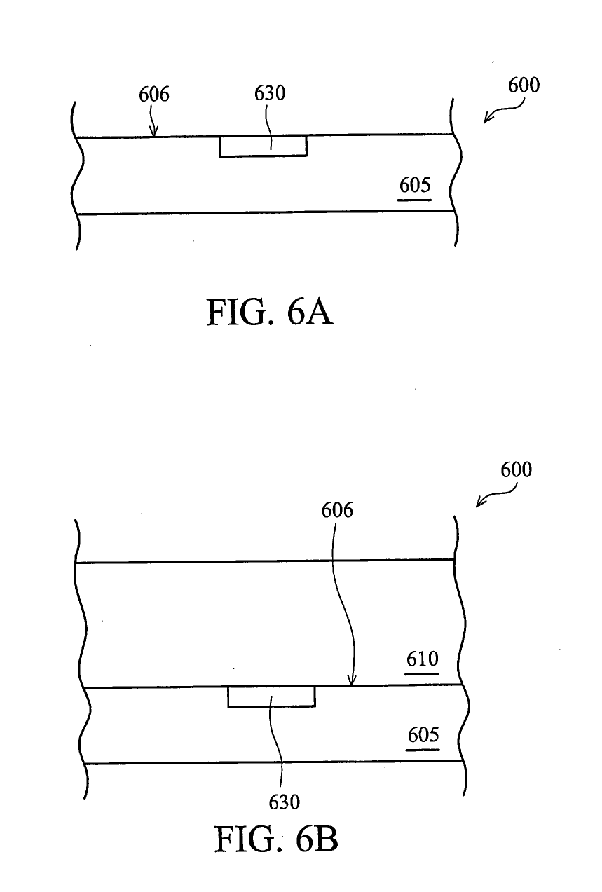

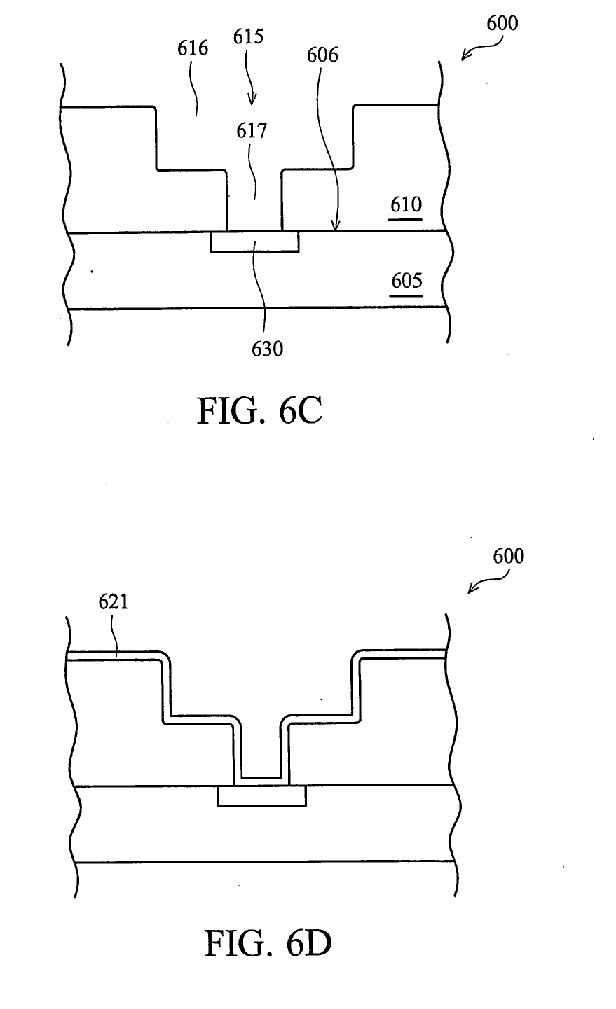

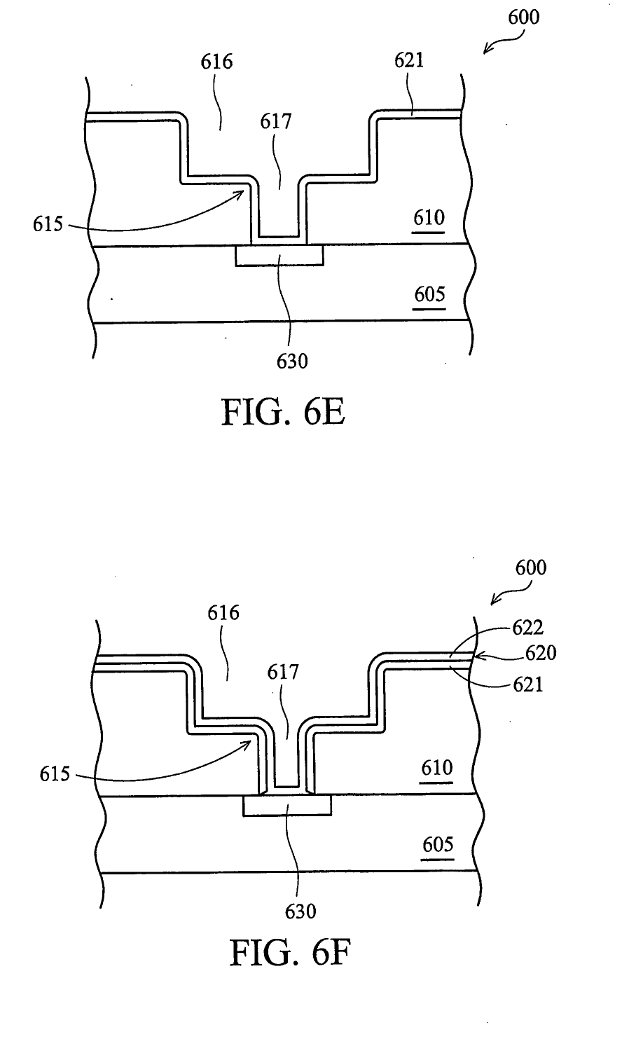

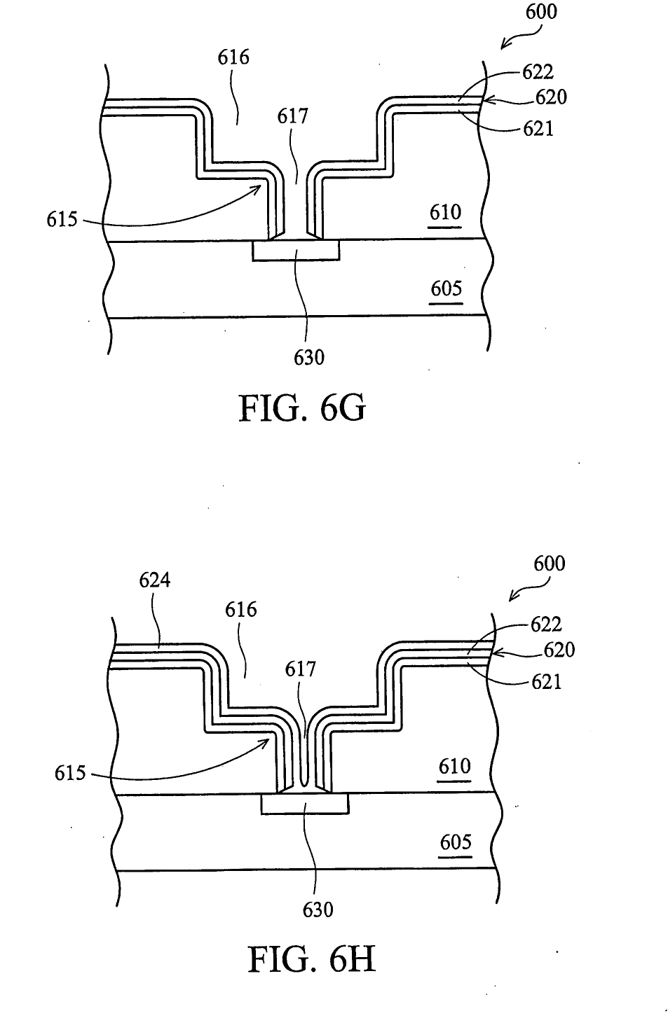

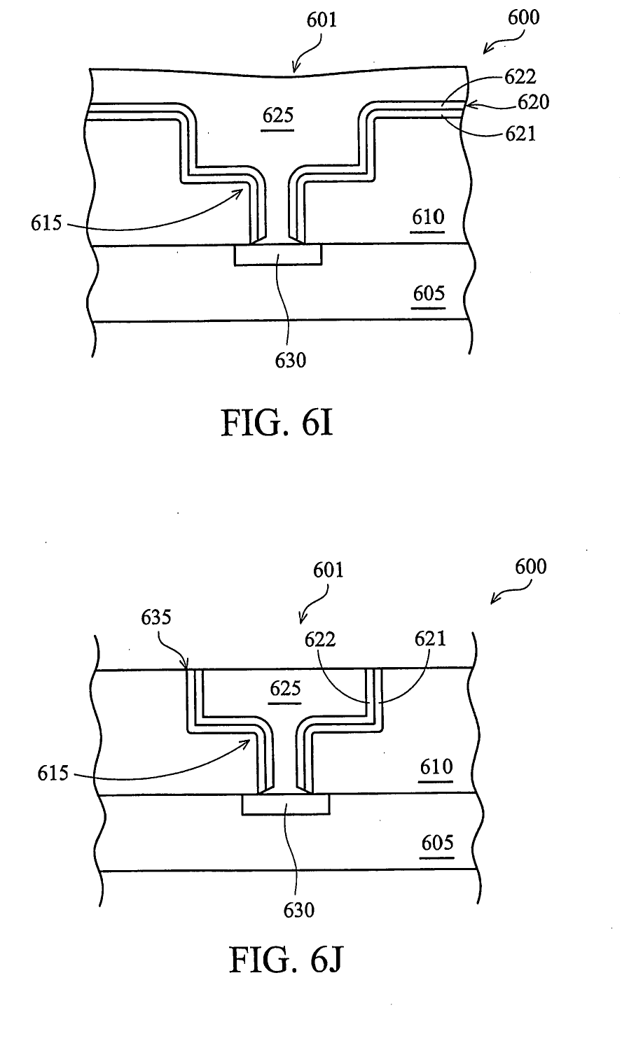

FIG. 5 is a flow diagram illustrating a method for fabricating a semiconductor device 500 that includes an interconnect structure formed according to an embodiment of the present invention. At START, it is presumed that a wafer substrate has been provided, and that the tools, environment, and materials needed for the method for fabricating a semiconductor device 500 have been furnished. In addition, it is generally presumed though not required that a number of components or active areas have already been formed on the wafer substrate, components that are to be connected by one or more interconnect structures at contact regions (see, for example, FIG. 6A). The function of the active components and the composition of the dielectric layer are not material to the present invention unless explicitly recited or apparent from the context.

The process then continues with depositing a dielectric material onto the substrate (step 505). The dielectric layer may consist, for example of silicon nitride (SiN), fluorinated silicate glass (FSG), carbon-doped oxide (CDO), or some other suitable dielectric material. More than one dielectric layer may, of course, be deposited at this stage (steps not separately shown). Where there is more than one dielectric layer, a barrier layer or etch stop layer may be deposited between them (step also not shown). At this point, the active components have been covered with one or more layers of dielectric material; the desired interconnects may then be formed within this dielectric layer. Note that there may be one or many such interconnects, and where many are present, it is not required that all are formed used the same method. Using a single method for each dielectric layer is, however, expected to be more convenient in most applications.

To form the interconnect according to this embodiment of the present invention, an interconnect recess is formed (step 510) in the dielectric material. The interconnect recess typically includes a trench portion extending along the wafer surface for holding the main conductor, and one or more via portions, which extend downward through the dielectric layer to the contact region layer at which a connection is desired. Formation of the interconnect recess is typically accomplished using one or more photolithography steps (not individually shown). For each step, a photoresist layer is applied, then selectively exposed to light and developed so that unprotected portions of the dielectric layer are etched away to create a pattern on the wafer surface. The interconnect recess trench and the interconnect recess vias may be formed at the same time or in sequence. Once the interconnect recess is formed at step 510, an optional cleaning step (not shown) may be performed prior to adding the barrier and seed layers.

To form the barrier layer according to this embodiment of the present invention, a tantalum nitride (TaN) film layer is first deposited (step 515). This TaN layer is preferably though not necessarily about 135 Å in width. The TaN layer is then re-sputtered (step 520). Re-sputtering involves the bombardment of the deposited layer with ions to effect a more optimal crystalline structure in material that has already been deposited. In this embodiment, argon ions (Ar⁺) are considered suitable for this purpose. The plasma used in re-sputtering is preferably maintained in a saturate concentration. Note that steps 515 and 520 may be performed more than once. The deposition of a tantalum (Ta) film layer is then performed (step 525), preferably though not necessarily forming a layer about 200 Å thick. The Ta is then re-sputtered (step 530), preferably to form a layer about 50 Å or more in thickness. Steps 525 and 530 may also be repeated more than once. As a result of the re-sputtering, the grain size of the barrier-layer materials has been increased, and this lower grain density results in a lower resistivity value for the completed interconnect. Ideally, the re-sputtering of the secondary film layer results in a grain density of approximately 3.5 per 100 nm or less.

After the barrier layer is formed, a copper seed layer may then be deposited (step 535). The seed layer is used as a reliable conductor for the copper electroplating of the next step. With the seed layer thus formed over the barrier layer, the copper forming the main conductor is deposited (step 540). In this embodiment, formation of the main conductor portion is performed using an electrochemical plating (ECP) process. The method for fabricating a semiconductor device 500 then finishes with the step of removing any excess copper (step 545) from what is now the surface of the wafer. In the embodiment of FIG. 5, the finished surface is produced using a (CMP) process. Further fabrication to for additional devices may now be performed. In many cases, an insulating layer may be deposited (step not shown) in order to electrically isolate the interconnect.

FIGS. 6A though 6J are cross-sectional elevation views illustrating a semiconductor device at selected stages of fabrication, according to the method of an embodiment of the present invention. FIG. 6A illustrates the semiconductor device 600 at an initial stage (generally corresponding with START shown in FIG. 5). In FIG. 6A, substrate 605 has been provided with an active area 630, here defined to include any location at or in the surface 606 of substrate 605 to which an electrical connection is to be made using an interconnect or similar structure. A layer of dielectric material 610 is then deposited, effectively covering the surface 606 of substrate 605, including active area 630, as shown in FIG. 6B. Here it is again noted the method of the present invention may be used in higher layers as well as in the dielectric layer covering the base wafer substrate. It is also noted that the dielectric layer 610 may include multiple layers of material, although that configuration is not shown in FIGS. 6B through 6J.

FIG. 6C illustrates the configuration of semiconductor device 600 after the interconnect (here, trench-and-via) recess 615 has been formed. In FIG. 6C, trench portion 616 and via portion 617 of interconnect recess 615 are visible, though there will usually be a number of via portions communicating with trench portion 616. The interconnect recess 615 may be cleaned, for example using an argon plasma at this stage in preparation for depositing the materials that make up the interconnect itself. In accordance with the present invention, the first of these is a thin barrier layer (or film) 621, preferably of Tantalum Nitride (TaN). TaN film 621 covers the interior surface of the interconnect recess as shown in FIG. 6D. A re-sputter of the interconnect recess 615 (and specifically of TaN film 621) effects a reduction in the resistivity of the TaN film 621 and tends to cause the TaN material deposited on the active area 630 to reform on the side wall of via 617, as illustrated in FIG. 6E. As noted above, this deposition and re-sputter procedure may be performed a number of times. The re-sputter is preferably performed using an argon plasma (Ar⁺) in a saturate condition. Note that controlling the plasma environment during the re-sputter enables control of the grain size and resistivity of the TaN film 621.

In the illustrated embodiment, a second barrier film 622 is then be applied, as shown in FIG. 6F, creating barrier layer 620, which includes the TaN film 621 and second barrier film 622. In a preferred embodiment, the second barrier film 622 is Tantalum (Ta). A re-sputter of the Ta film 622 is then also performed, and the Ta deposition and re-sputter may at this time also be repeated. The resulting structure is shown in FIG. 6G. A seed layer 624, preferably of copper, is then deposited over the barrier layer 620, as illustrated in FIG. 6H. Finally, the conductor material 625, which is also preferably copper, is deposited over the entire structure, yielding the interconnect 601 of semiconductor device 600 as shown in FIG. 6I. To complete fabrication of the interconnect 601, a CMP step removes the excess copper and creates a planar surface 635 (as shown in FIG. 6J) upon which the next fabrication step (whatever that may be) may be performed.

Although the present invention and its advantages have been described in detail, it should be understood that various changes, substitutions and alterations can be made herein without departing from the spirit and scope of the invention as defined by the appended claims. For example, other materials or combinations of materials may be used, and the interconnect structure may take other shapes rather than the trench and via profile illustrated herein. And, as it will be readily understood by those skilled in the art, the step of the processes described herein may be performed in any logically consistent order while remaining within the scope of the present invention.

Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

What is claimed is:

1. A method for fabricating a semiconductor device, said method comprising the steps of:
providing a substrate having a contact region;
depositing a dielectric layer over the substrate;
forming an interconnect recess in the dielectric layer;
depositing a tantalum nitride (TaN) film within the recess;
re-sputtering the TaN film;
depositing a tantalum (Ta) film over the TaN film; and
re-sputtering the Ta film.

2. The method according to claim 1, further comprising the step of forming a seed layer.

3. The method according to claim 2, further comprising the step of filling the interconnect recess with a conductor.

4. The method according to claim 3, further comprising the step of removing any excess conductor material.

5. The method according to claim 4, wherein the excess material is removed by a chemical mechanical polishing (CMP) operation.

6. The method according to claim 3, wherein the conductor and the seed layer are formed of copper material.

7. The method according to claim 1, wherein the interconnect recess is a trench in communication with a via that extends to the contact region.

8. The method according to claim 1, further comprising the step of cleaning the interconnect recess prior to depositing the TaN film.

9. The method according to claim 1, wherein the re-sputtering steps are performed using an argon plasma.

10. The method according to claim 9, wherein the argon plasma is maintained in a saturate condition during the re-sputtering.

11. A method of forming an interconnect for use as an electrical connection in a semiconductor device, comprising the steps of:
providing a dielectric layer;
forming an interconnect recess;
forming a first barrier layer film;
forming a second barrier layer film on the first barrier layer film;
performing a re-sputtering operation subsequent to forming the second barrier layer film;
forming a seed layer; and
forming a layer of conducting material to substantially fill the interconnect recess.

12. The method of forming an interconnect of claim 11, wherein the interconnect recess is a trench-and-via type recess.

13. The method of forming an interconnect of claim 11, wherein the first barrier layer film is formed of a tantalum nitride material.

14. The method of forming an interconnect of claim 11, wherein the second barrier layer film is formed of a tantalum material.

15. The method of forming an interconnect of claim 11, wherein the re-sputtering operation is performed using an argon plasma.

16. The method of forming an interconnect of claim 11, further comprising the step of performing a re-sputtering operation subsequent to forming the first barrier layer film.

17. The method of forming an interconnect of claim 11, wherein the seed layer is formed of the same material as the conducting material used to substantially fill the interconnect recess.

18. An interconnect for coupling with a contact region on a semiconductor wafer substrate, comprising:
a dielectric layer over the substrate, the dielectric layer forming a recess;
a TaN layer formed within the recess;
a Ta layer formed within the recess;
wherein the Ta layer exhibits a grin density less than or equal to approximately 3.5 per 100 nm; and
a conductor formed in the recess over the TaN layer.

19. The interconnect of claim 18, wherein the Ta layer thickness is greater than or equal to approximately 50 Å.

20. The interconnect of claim 18, wherein the TaN layer thickness is within the range of approximately 50 Å to 150 Å, inclusive.

21. The interconnect of claim 20, wherein the TaN layer thickness is approximately 135 Å.

22. The interconnect according to claim 18, wherein the Ta layer is formed over the TaN layer.

23. The interconnect according to claim 22, further comprising a seed layer formed over the Ta layer.

24. The interconnect according to claim 22, wherein the conductor is copper.

25. The interconnect according to claim 22, wherein the TaN layer is formed by depositing a TaN film and then re-sputtering the TaN film.

26. The interconnect according to claim 25, where in the re-sputtering is performed with argon ions (Ar⁺).
